(19) United States
(12) Patent Application Publication
(10) Pub. No.: US 2024/0332285 A1
(43) Pub. Date: Oct. 3, 2024

(54) CIRCUIT COMPONENTS WITH HIGH PERFORMANCE THIN FILM TRANSISTOR MATERIAL

(71) Applicant: Intel Corporation, Santa Clara, CA (US)

(72) Inventors: Sukru Yemenicioglu, Portland, OR (US); Abhishek Anil Sharma, Portland, OR (US); Sudipto Naskar, Portland, OR (US); Kalyan C. Kolluru, Portland, OR (US); Chu-Hsin Liang, Santa Cruz, CA (US); Bashir Uddin Mahmud, Portland, OR (US); Van Le, Beaverton, OR (US)

(73) Assignee: Intel Corporation, Santa Clara, CA (US)

(21) Appl. No.: 18/129,702

(22) Filed: Mar. 31, 2023

(51) Int. Cl. H01L 27/02; H01L 21/84; H01L 29/66; H01L 29/786; H01L 29/872; H02H 9/04

(52) U.S. Cl. CPC H01L 27/0266; H01L 21/84; H01L 27/0255; H01L 27/0296; H01L 29/6603; H01L 29/66143; H01L 29/66212; H01L 29/66522; H01L 29/66742; H01L 29/66969; H01L 29/78696; H01L 29/872; H02H 9/046

(57) ABSTRACT

An integrated circuit device comprising a resistor formed on a non-crystalline substrate, the resistor comprising a gate electrode; a gate dielectric in contact with the gate electrode; a source electrode and a drain electrode; and a thin film transistor TFT channel material coupled between the source electrode and the drain electrode.

### BACKGROUND

In some semiconductor processes, such as those where the transistor technology relies on gate-all-around devices or variants thereof, fabrication of P-N junctions and resistors for purposes such as electrostatic discharge (ESD) protection becomes very challenging. Such fabrication may include modifications to the processes used for digital logic transistors as well as additional process steps on the front end, which may impact the performance of the digital logic transistors (e.g., due to parasitic connections), result in extra cost, and pose a yield risk.

### BRIEF DESCRIPTION OF THE DRAWINGS

FIG. 1 illustrates a circuit implementing electrostatic discharge (ESD) protection, in accordance with any of the embodiments disclosed herein.

FIGS. 2A-2B illustrate a diode comprising a high performance thin film transistor (HP TFT) material, in accordance with any of the embodiments disclosed herein.

FIGS. 3A-3B illustrate phases of manufacture of the diode of FIGS. 2A-2B, in accordance with any of the embodiments disclosed herein.

FIG. 4 illustrates a diode in which HP TFT material is vertically stacked between an anode and cathode, in accordance with any of the embodiments disclosed herein.

FIG. 5 illustrates diodes in which HP TFT material is formed between an anode and cathode in a horizontal grating configuration, in accordance with any of the embodiments disclosed herein.

FIG. 6 illustrates phases of manufacture of diodes in a horizontal grating configuration, in accordance with any of the embodiments disclosed herein.

FIGS. 7A-7B illustrate a resistor comprising an HP TFT material, in accordance with any of the embodiments disclosed herein.

FIGS. 8A-8B illustrate phases of manufacture of the resistor of FIGS. 7A-7B, in accordance with any of the embodiments disclosed herein.

FIG. 9 illustrates a schematic of a cross-sectional view of an example integrated circuit device, in accordance with any of the embodiments disclosed herein.

FIG. 10 is a top view of a wafer and dies that may be included in a microelectronic assembly, in accordance with any of the embodiments disclosed herein.

FIG. 11 is a cross-sectional side view of an integrated circuit device that may be included in a microelectronic assembly, in accordance with any of the embodiments disclosed herein.

FIGS. 12A-12D are perspective views of example planar, FinFET, gate-all-around, and stacked gate-all-around transistors.

FIG. 13 is a cross-sectional side view of an integrated circuit device assembly that may include a microelectronic ASSEMBLY, in accordance with any of the embodiments disclosed herein.

FIG. 14 is a block diagram of an example electrical device that may include a microelectronic assembly, in accordance with any of the embodiments disclosed herein.

### DETAILED DESCRIPTION

As alluded to above, diodes and resistors may be difficult to form in certain semiconductor processes (e.g., due to area constraints or other limitations due to transistor size). In various embodiments of the present disclosure, diodes and/or resistors may be formed with a high performance thin film transistor (HP TFT) material, significantly easing manufacturing constraints. In various embodiments, the HP TFT material is a versatile material that can be grown on a non-crystalline substrate. Thus the diodes and resistors are not required to be placed on a silicon or other crystalline substrate on the front side of the wafer, but may be formed, in some embodiments, on the back side of the wafer (e.g., on the side of the wafer opposite to the front side of the wafer which comprises the front-end-of-line (FEOL) and back-end-of-line (BEOL) structures). Placing the diodes and/or resistors on the back side of the wafer (or in a location on the front side of the wafer away from the FEOL, such as the BEOL) may free up space on the front end and simplify certain processing steps on the front end. This may also additionally or alternatively allow the patterning of diodes and resistors independent on the limitations around the transistor technology (e.g., gate-all-around or other suitable technology) used. In some embodiments, an HP TFT with an extended gate at the wafer backside may be used as a resistor. Various embodiments including such a resistor may reduce process challenges, enable a high degree of design flexibility, provide tunability of the resistance, and/or reduce variation.

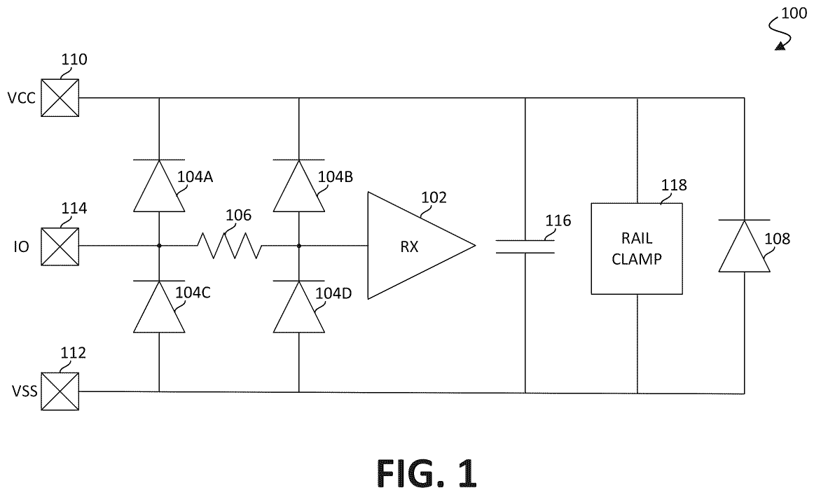

FIG. 1 illustrates a circuit 100 implementing electrostatic discharge (ESD) protection, in accordance with any of the embodiments disclosed herein. Although the circuit components described herein may be used for any suitable purpose in an integrated circuit, they may find particularly valuable application in ESD protection.

Circuit 100 comprises a receiver 102 to receive an input signal from an I/O pad 114, a plurality of diodes 104 (e.g., 104A-104D) to be reverse biased by a voltage provided by a Vcc pad 110 and Vss pad 112, a resistor 106 coupled between the I/O pad 114 and receiver 102 (and also to the diodes 104), a decoupling capacitor 116, a rail clamp 118, and another diode 108.

Any number of the diodes 104 and/or the resistor 106 in the depicted embodiment may comprise an HP TFT material. In various embodiments, diodes 104 are each Schottky diodes and may protect the receiver 102 from damage from excessive current caused by ESD. The resistor 106 may facilitate a drop in voltage in the input signal before the I/O signal reaches the receiver 102.

Capacitor 116 is a decoupling capacitor. In various embodiments, the capacitor (or at least a portion thereof) is formed on the front end of the integrated circuit device. The rail clamp 118 comprises a clamping structure which may detect and sink current.

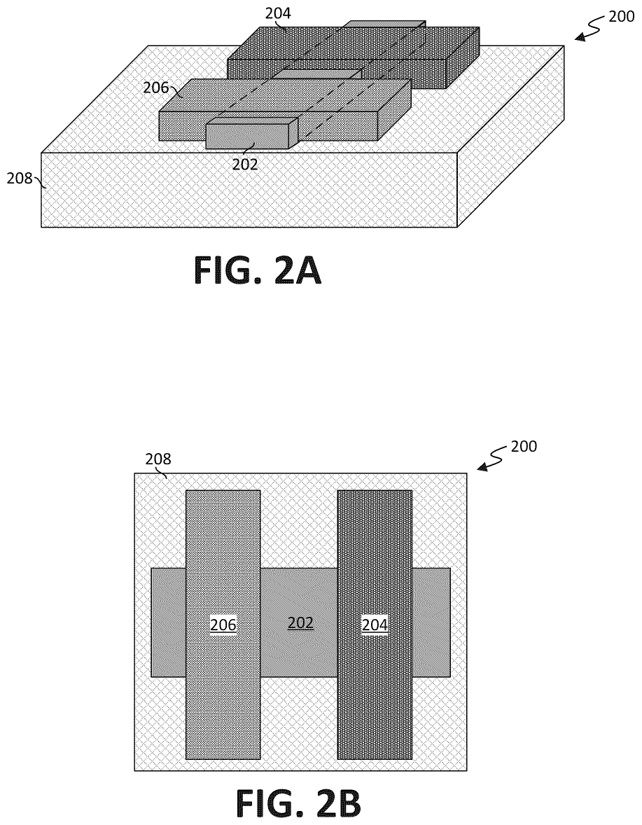

FIGS. 2A-2B illustrate a diode 200 comprising an HP TFT material 202, in accordance with any of the embodiments disclosed herein. FIG. 2A is a perspective view and FIG. 2B is a top view of the diode 200.

In this embodiment, HP TFT material 202 is formed in a strip that passes through two strips of conductive contacts (e.g., anode 204 and cathode 206). HP TFT material 202 runs through the width of both the anode 204 and the cathode 206. In this embodiment, the HP TFT material 202 is substantially orthogonal to the anode 204 and cathode 206 (and the anode 204 and cathode 206 are substantially parallel to each other). The HP TFT material 202, the anode 204, and the cathode 206 are each formed above the substrate 208.

The portion of the HP TFT material 202 that passes through the anode 204 forms an ohmic contact (e.g., a junction between two conductors that has a linear current-voltage curve) with the anode 204. In some embodiments, the anode 204 may directly contact the HP TFT material 202 to form the ohmic contact, while in other embodiments, an intermediate material may be formed between the HP TFT material 202 and the anode 204 to facilitate a low resistance between the HP TFT material 202 and the anode 204. In various embodiments, the HP TFT material 202 and the material used to form the anode 204 may have substantially similar work functions, such that a Schottky barrier is not formed between the anode 204 and the HP TFT material 202. The intermediate material may comprise any suitable material to facilitate the ohmic contact, such as a degenerate semiconductor, such as doped polysilicon or other doped semiconductor with free available charge carriers.

The portion of the HP TFT material 202 that passes through the cathode 206 may directly contact the cathode 206. In various embodiments, the HP TFT material 202 and the material used to form the cathode 206 may have respective work functions that cause a Schottky barrier to be formed between the cathode 206 and the HP TFT material 202 (e.g., the work functions of the cathode material and the HP TFT material may be substantially different). Thus, a P-N junction may be formed at the interface between the cathode 206 (e.g., a metal) and the HP TFT material 202 (e.g., a semiconductor). In various embodiments, the cathode material may be chosen such that the resulting Schottky diode has a relatively low reverse bias for current conduction.

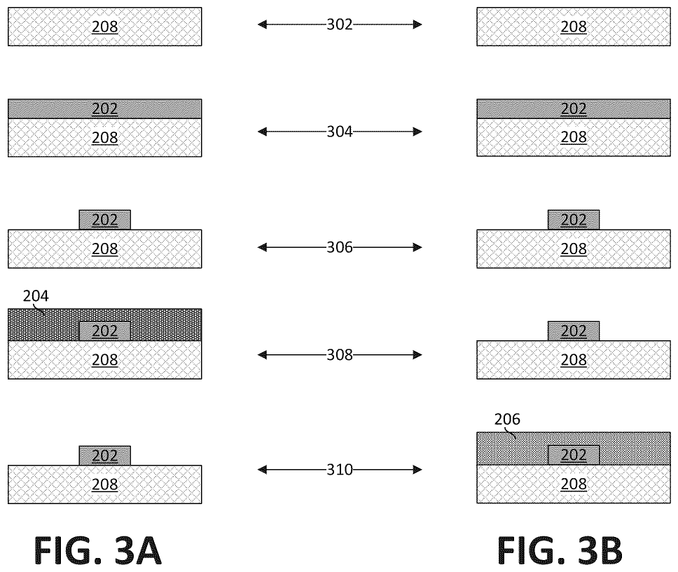

FIGS. 3A-3B illustrate phases of manufacture of the diode of FIGS. 2A-2B, in accordance with any of the embodiments disclosed herein. The structures shown in the left column correspond to a cross section of the diode 200 at the anode 204 while the structures shown in the right column correspond to a cross section of the diode 200 at the cathode 206.

At phase 302, the substrate 208 is formed. At phase 304, a layer of HP TFT material 202 is formed over the substrate 208. The HP TFT material 202 may be formed in any suitable manner, such as through atomic layer deposition (ALD), chemical vapor deposition (CVD), physical vapor deposition (PVD), or other suitable technique.

At phase 306, portions of the HP TFT material 202 are removed to obtain the desired profile of the HP TFT material. The HP TFT material 202 may be removed in any suitable manner, such as through etching or other suitable technique.

At phase 308, the anode 204 is formed over (e.g., on) the substrate and the HP TFT material 202 on the anode side. In various embodiments, the cathode side may be masked during deposition of the anode material.

At phase 310, the cathode 206 is then formed over the substrate 208 and the HP TFT material 202 on the cathode side. The anode side may be masked during deposition of the cathode material. In other embodiments, the cathode 206 3 may be formed before the anode 204.

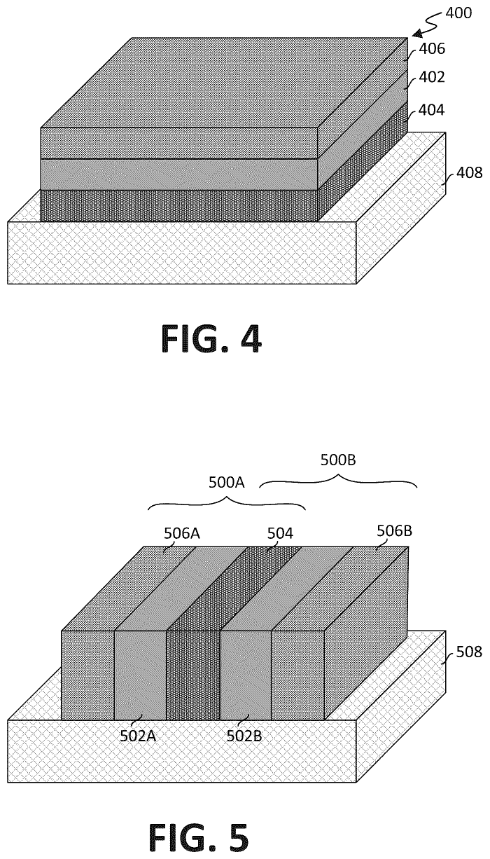

FIG. 4 illustrates a diode in which HP TFT material 402 is vertically stacked between an anode 404 and cathode 406, in accordance with any of the embodiments disclosed herein. In various embodiments, an intermediate material (not shown) may also be formed between the HP TFT material 402 and the anode 404, such that the anode 404 and the HP TFT material 402 form an ohmic contact. The various layers are all stacked on a substrate 408. In various embodiments, the stack may be repeated any number of times. For example, another substrate 408 may be placed on top of cathode 406 and the stack may be repeated. As another example, another layer of HP TFT material 402 may be formed above the cathode 406, then another anode 404, then another layer of HP TFT material 402, then another cathode 406, and so on.

FIG. 5 illustrates diodes 500 (e.g., 500A, 500B) in which HP TFT material 502 (e.g., 502A, 502B) is formed between an anode 504 and a respective cathode 506 (e.g., 506A, 506B) in a horizontal grating configuration, in accordance with any of the embodiments disclosed herein. In this embodiment, the sidewalls of an element contacts the sidewalls of adjacent elements. In some embodiments, an intermediate material (not shown) may be formed between each segment of HP TFT material 502 and anode 504 to facilitate formation of ohmic contacts. The various elements are all stacked on a substrate 508.

In this embodiment, the diodes 500 may share a common anode 504. In various embodiments, diodes may share anodes or cathodes, or may each comprise a distinct anode and cathode. Signal lines may be coupled to the anodes and cathodes in any suitable manner to form diodes 500 in series, diodes 500 in parallel, etc. In other embodiments, additional elements may be formed on either side (or both sides) of the elements in the grating configuration on the substrate 508 to form any number of adjacent diodes 500.

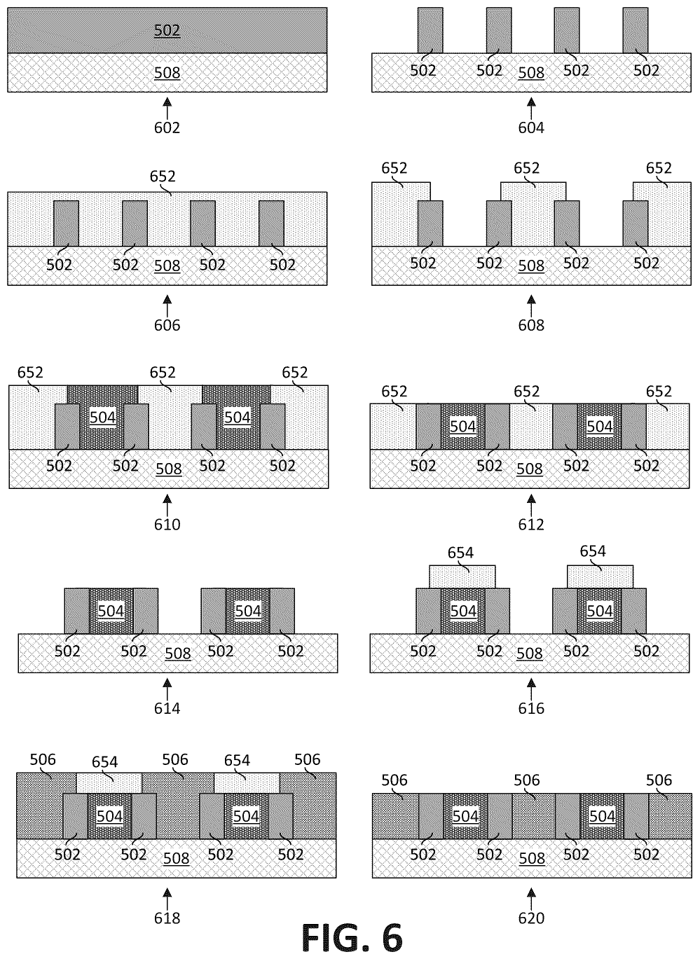

FIG. 6 illustrates phases of manufacture of diodes in a horizontal grating configuration, in accordance with any of the embodiments disclosed herein. At phase 602, a layer of HP TFT material 502 is formed on a substrate 508. At 604, unwanted portions of the HP TFT material 502 are removed.

At 606, a mask material 652 is formed over (e.g., on) the substrate 508 and the segments of HP TFT material 502. At 608, portions of the mask material 652 are removed, leaving gaps in between some pairs of adjacent segments of HP TFT material 502.

At 610, material for anodes 504 is formed in the gaps left after phase 608. At 612, excess materials (e.g., above the top of the segments of HP TFT material 502) are removed (e.g., via a polish step or other suitable technique).

At 614, the remaining masking material 652 is removed. At 616, masking material 654 is formed over the anodes 504 to protect them from mixing with the cathode material. The masking material 654 may be the same as masking material 652 or may be a different masking material in various embodiments.

At 618, material for cathodes 506 is formed in the gaps between segments of HP TFT material 502. At 620, excess materials (e.g., above the top of the segments of HP TFT material 502 and anodes 504) are removed (e.g., via a polish step or other suitable technique).

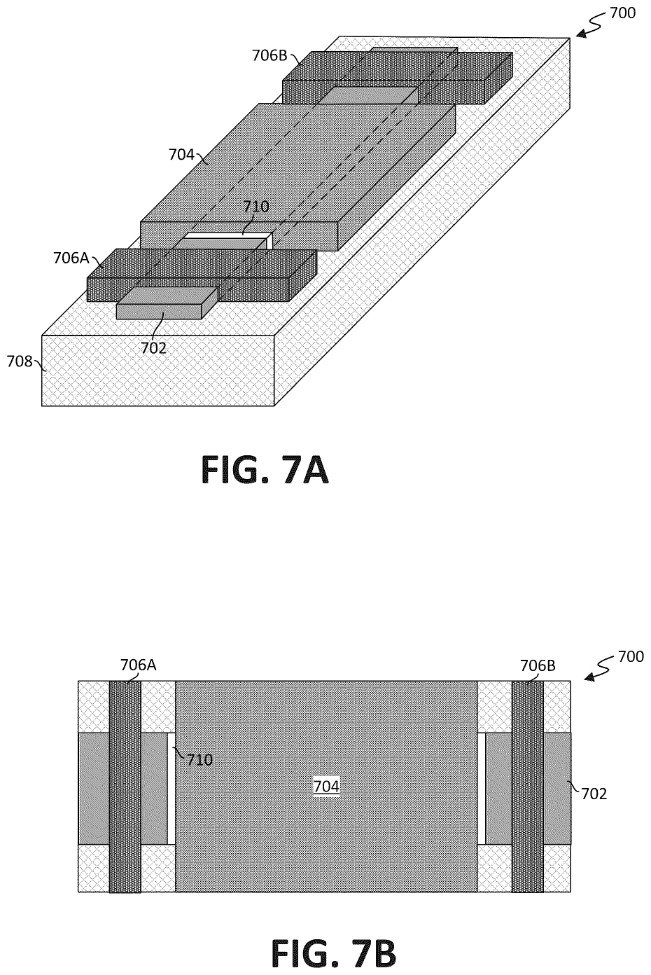

FIGS. 7A-7B illustrate a resistor 700 comprising an HP TFT material 702, in accordance with any of the embodiments disclosed herein. FIG. 7A is a perspective view of the resistor 700 and FIG. 7B is a top-down view of the resistor 700.

In various embodiments, the resistor 700 is a TFT with an extended gate electrode (e.g., 704), in effect, the resistor 700 is a very long transistor. A TFT is a special kind of a field-effect transistor made by depositing a thin-film of an active semiconductor material (e.g., HP TFT material 702), as well as a gate dielectric (e.g., 710) and metallic (or other conductive) contacts (e.g., S/D electrodes 706), over a support layer (e.g., substrate 708) that may be a non-conducting layer. At least a portion of the active semiconductor material forms a channel of the TFT, through which charge carriers (e.g., electrons or holes) flow from a source to a drain of the transistor. This differs from conventional, non-TFT, front-end-of-line (FEOL) logic transistors where the active semiconductor channel material is typically a part of a semiconductor substrate, e.g., a part of a silicon wafer.

TFTs (such as resistor 700 or other suitable TFTs) may be formed at any suitable location of an integrated circuit device. For example, in various embodiments, TFTs may be formed in the same plane as the FEOL logic transistors. In other embodiments, since an HP TFT material may be deposited at a relatively low temperature, the HP TFT may be deposited within the thermal budgets imposed on back end fabrication to avoid damaging the front end components (e.g., FEOL logic transistors) and thus may be formed in the back-end-of-line (BEOL) regions. In yet other embodiments, the TFTs may be formed on the back side of a wafer.

In various embodiments, the HP TFT material 702 may be deposited using atomic layer deposition (ALD), chemical vapor deposition (CVD), or physical vapor deposition (PVD), or other suitable technique. In various embodiments, the HP TFT material is a versatile material that can be grown on any suitable substrate (e.g., 208, 408, 508, 708) such as a crystalline (e.g., a silicon or other crystalline substrate) or a non-crystalline structure (e.g., a dielectric material, such as silicon oxide, silicon nitride, a metal oxide (e.g., aluminum oxide), other oxide, silicon oxynitride, etc.). Thus, the HP TFT material may be grown independent of a semiconductor substrate in particular embodiments.

The transistor that implements resistor 700 may operate in the saturation region and may be programmable in that the programmable resistor may be turned on (resulting in a first resistance between the S/D terminals) or off (resulting in a second resistance between the S/D terminals) based on an applied bias voltage. Thus,

The resistor 700 may be tuned for various applications (e.g., I/O, ESD protection, etc.) by designing the dimensions (e.g., gate length) accordingly to achieve the desired resistance. In various examples, the resistor 700 may be designed for applications such as terminations in I/O circuits or resistance for inductor connections (where the inductor and the resistor 700 may both be on the backside of the wafer).

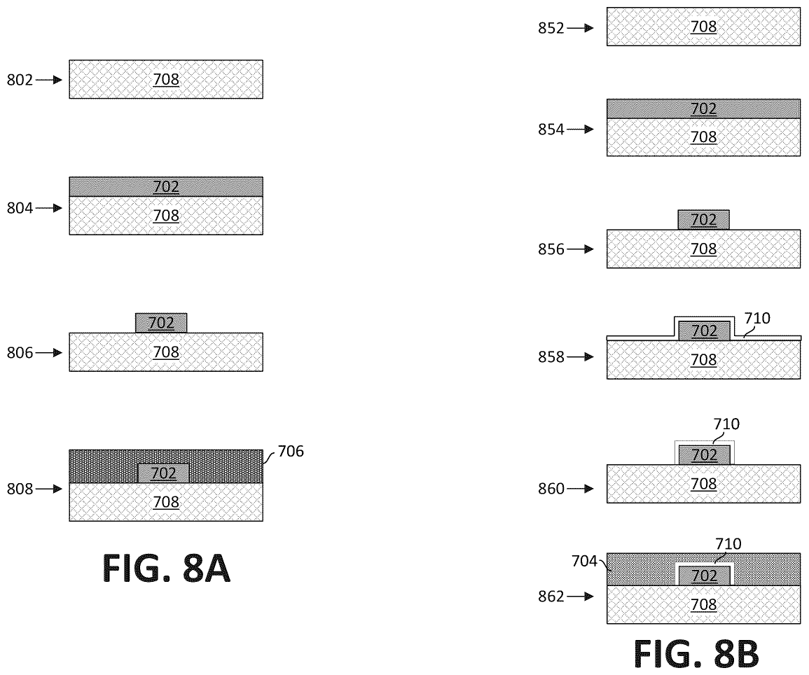

FIGS. 8A-8B illustrate phases of manufacture of the resistor of FIGS. 7A-7B, in accordance with any of the embodiments disclosed herein. FIG. 8A represents phases of manufacture of the resistor at a cross section of an S/D electrode (e.g., 706A or 706B), while FIG. 8B represents phases of manufacture of the resistor at a gate electrode (e.g., 704).

Referring to FIG. 8A, at phase 802, a substrate 708 is formed. At phase 804, a layer of HP TFT material 702 is formed above the substrate 708. At phase 806, undesired portions of the HP TFT material 702 is removed. At phase 808, the S/D electrode 706 is formed over the substrate 708 and a portion of the HP TFT material 702. The S/D electrode 706 may form an ohmic contact with the HP TFT material 702.

Referring to FIG. 8B, at phase 852, a substrate 708 is formed. At phase 854, a layer of HP TFT material 702 is formed above the substrate 708. At phase 856, undesired portions of the HP TFT material 702 is removed. At phase 858, a layer of a gate dielectric 710 is formed above the substrate 708 and the HP TFT material 702. At phase 860, undesired portions of the gate dielectric 710 are removed. At phase 862, the gate electrode 704 is formed over the substrate 708 and over and around the HP TFT material 702 and gate dielectric 710.

In various embodiments, some of the phases may be performed simultaneously. For example, the substrate 708 of phases 802 and 852 may be the same substrate. Similarly, the HP TFT material 702 of phases 804 and 854 may be deposited in the same process step and the portions removed in phases 806 and 856 may be removed in a common process step. Similarly, some of the phases (e.g., formation of the gate dielectric 710 may be performed simultaneously with corresponding phases for forming other TFTs or other circuit components (e.g., diodes 200, 400, 500).

Transistors (e.g., TFTs, non-TFT transistors) that may be included in the same integrated device as one or more circuit elements described herein may include various components, including one or more of a substrate, S/D electrodes, gate electrodes, gate dielectrics, a channel material (e.g., HP TFT material, the substrate material, etc.). Various examples for such components (as well as examples for components of the circuit elements discussed above) are now described.

In various embodiments, an HP TFT material (also referred to as an HP TFT channel material) (e.g., 202, 402, 502, 702) may comprise a semiconductor material exhibiting a high mobility and a wide bandgap voltage. In various embodiments, the HP TFT material is not a single crystalline material (e.g., silicon), but is amorphous, polycrystalline, or nanocrystalline.

In various embodiments, the charge carrier mobility of the HP TFT material is higher than 5 cm cm²/(V·s), higher than 20 cm²/(V·s), higher than 50 cm²/(V·s), or higher than 100 cm²/(V·s). In various embodiments, the mobility of the HP TFT material is between 5 cm²/(V·s) and 700 cm²/(V·s), including all values and ranges therein (including the range from 50 cm²/(V·s) to 700 cm²/(V·s) and the range from 100 cm²/(V·s) to 700 cm²/(V·s)). At least in some embodiments, these ranges may be critical as they represent a range for mobility that is high enough to function as an HP TFT channel material, which is generally difficult to achieve with an amorphous, nanocrystalline, or polycrystalline material. When the HP TFT material is used to form a resistor, a slightly lower mobility (e.g., greater than 5 cm²/(V·s) is likely acceptable, though not required. When used to form a diode, a higher mobility may be advantageous (e.g., greater than 50 cm²/(V·s)) though embodiments aren't limited thereto.

In various embodiments, the bandgap voltage of the HP TFT material is higher than the bandgap voltage of silicon (e.g., 1.14 eV @ 300K). In some examples, the bandgap voltage of the HP TFT material is materially higher than the bandgap voltage of silicon (e.g., higher than 1.2 eV @ 300K). In particular embodiments, the bandgap voltage of the HP TFT material is higher than the bandgap voltage of silicon but lower than 6.5 eV @ 300K, including all values and ranges therein. In various embodiments, the bandgap voltage of the HP TFT material is higher than the bandgap voltage of a substrate upon which a transistor comprising the HP TFT material is formed. In some embodiments, these ranges may be critical as they represent a range for a bandgap voltage that may protect against channel breakdown.

In various embodiments, the HP TFT material comprises an oxide (e.g., a metal oxide), such as indium gallium zinc oxide (IGZO), indium tin oxide (ITO), indium xinc oxide (IZO), zinc oxide, indium oxide, gallium oxide, copper oxide, tin oxide, or other suitable oxide. In some oxides, a material with insulating properties may be introduced into the oxide to increase the bandgap voltage. For example, doping indium oxide with hafnium oxide (which exhibits insulating properties) will result in a composite HP TFT material with a wider bandgap than the indium oxide. Similarly, indium oxide or zinc oxide may be doped with gallium oxide (which exhibits insulating properties) to produce a composite HP TFT material with a wider bandgap voltage.

In some embodiments, the HP TFT material comprises a nitride (e.g., a metal nitride), such as zinc nitride, indium nitride, gallium nitride, copper nitride, aluminum nitride, or other suitable nitride. In some nitrides, a material with insulating properties may be introduced into the nitride to increase the bandgap voltage. For example, aluminum nitride (which exhibits insulating properties) may be added to indium nitride, zinc nitride, or gallium nitride to produce a composite HP TFT material with an increased bandgap voltage.

In some embodiments, the HP TFT material comprises a chalcogenide, such as a selenide or sulfide of molybdenum, tungsten, indium, gallium, zinc, copper, hafnium, aluminum, or germanium.

In some embodiments, the HP TFT material comprises any other suitable material, such as black phosphorous, graphene, carbon nanotubes, polysilicon, poly germanium, poly (3,5) (gallium arsenide, etc.). While some of these materials have a narrower bandgap voltage than silicon in certain compositions, the concentration of certain elements (e.g., gallium) may be increased to improve the bandgap voltage of the resulting HP TFT material.

The S/D electrodes (e.g., 706) may be coupled to HP TFT material (e.g., 702). In some examples, the S/D electrodes may form ohmic contacts with the HP TFT material. As is commonly known, source and drain terminals are interchangeable in transistors (hence, the notation “S/D” terminals is sometimes used, indicating the interchangeability of the source and drain terminals). Therefore, while some examples and illustrations may be presented here with reference to source and drain electrodes, in other embodiments, any of source or drain terminals may be reversed.

S/D electrodes (e.g., 706) or other conductive contacts described herein (e.g., anodes or cathodes, such as 204, 206, 404, 406, 504, 506) may include any suitable electrically conductive material, alloy, or a stack of multiple electrically conductive materials. In some embodiments, the S/D electrodes or other conductive contacts may include one or more metals or metal alloys, comprising one or metals, e.g., copper, ruthenium, palladium, platinum, cobalt, nickel, hafnium, tungsten, molybdenum, gold, zirconium, titanium, tantalum, and aluminum, tantalum nitride, titanium nitride, tungsten, doped silicon, doped germanium, or alloys and mixtures of these. In some embodiments, the S/D electrodes or other conductive contacts may include one or more electrically conductive alloys, oxides, or carbides of one or more metals. In some embodiments, the S/D electrodes or other conductive contacts may include a doped semiconductor, such as silicon or another semiconductor doped with an N-type dopant or a P-type dopant. Metals may provide higher conductivity, while doped semiconductors may be easier to pattern during fabrication.

A gate dielectric (e.g., 710 may be provided to separate (e.g., to be between) the channel material (e.g., HP TFT material 702) and the gate electrode 704. In various embodiments, the gate dielectric 710 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric to improve its quality when a high-k material is used.

In some cases, a gate dielectric may include multiple layers, such as a first layer of high-k material (e.g., hafnium oxide) in contact with a gate electrode and a second layer of lower-k oxide between the first layer and the channel material. The lower-k oxide may be, for instance, silicon oxide or an oxide of the channel layer material. In various embodiments, the one or more layers of a gate dielectric may include e.g., silicon oxide, silicon dioxide, silicon carbide, and/or a high-k dielectric material.

A gate electrode (e.g, 704) may include any suitable conductive material such as polysilicon, a metal, or a metal alloy. Example suitable metals or metal alloys include aluminum, tungsten, cobalt, molybdenum, ruthenium, titanium, tantalum, copper, and carbides and nitrides thereof. In various embodiments, a gate electrode may include at least one P-type work function metal or N-type work function metal, depending on whether the respective transistor is a P-type transistor or an N-type transistor. For a P type transistor, metals that may be used for the gate electrode may include, but are not limited to, ruthenium, gold, palladium, platinum, cobalt, nickel, and conductive metal oxides (e.g., ruthenium oxide). For an N type transistor, metals that may be used for the gate electrode include, but are not limited to, hafnium, zirconium, titanium, tantalum, aluminum, alloys of these metals, and carbides and nitrides of these metals (e.g., hafnium carbide, zirconium carbide, titanium carbide, tantalum carbide, aluminum carbide, titanium nitride, and tantalum nitride).

In some embodiments, the gate electrode may include a stack of two or more metal layers, where one or more metal layers are work function metal layers and at least one metal layer is a fill metal layer or inner plug layer. Further metal layers may be included for other purposes, such as to act as a diffusion barrier layer.

In one example, a circuit element described herein may comprise an HP TFT material comprising a nitride (e.g., InN, InZnN, GaN, InGaN with oxygen, sulphur and/or phosphorus additions). In another example, the circuit element may comprise an HP TFT material comprising a ZnN film with a bandgap voltage ranging from 1.3 to 3 eV (depending on the N content) with a mobility exceeding 100 cm2/Vs. The circuit element may also comprise a gate dielectric comprising HfZrOx and/or a conductive contact, S/D electrode, and/or gate electrode comprising Ta, Ti, TiN or W.

A substrate (e.g., 208, 408, 508, 708) may comprise any suitable dielectric material such as a crystalline or a non-crystalline structure (e.g., such as silicon oxide, silicon nitride, a metal oxide (e.g., aluminum oxide), other oxide, or silicon oxynitride, etc.). In some embodiments, a non-crystalline substrate may refer to a wafer or thin templating layer that is amorphous, polycrystalline, or nanocrystalline (e.g., each nanocrystallite grain not exceeding 1 nanometer), e.g., it has a short range order. The non-crystalline substrate may be a layer or a bulk substrate.

A substrate used, e.g., for formation of transistors or other circuit elements may be, for example, a bulk substrate including group IV semiconductor material (such as silicon, germanium, or silicon germanium), group III-V semiconductor material (such as gallium arsenide, indium gallium arsenide, or indium phosphide), and/or any other suitable material from and/or upon which transistors or circuit elements can be formed. Alternatively, the substrate can be a semiconductor-on-insulator substrate having a desired semiconductor layer over a buried insulator layer (e.g., silicon over silicon dioxide). Alternatively, the substrate can be a multilayer substrate or superlattice suitable for forming nanowires or nanoribbons (e.g., alternating layers of silicon and SiGe, or alternating layers of indium gallium arsenide and indium phosphide).

Various elements of the components described herein (e.g., HP TFT material, cathodes, anodes, dielectric materials, substrates, intermediate materials, etc.) with respect to one or more particular FIGs. may have any suitable characteristics of corresponding elements described with respect to other FIGs. or elsewhere herein.

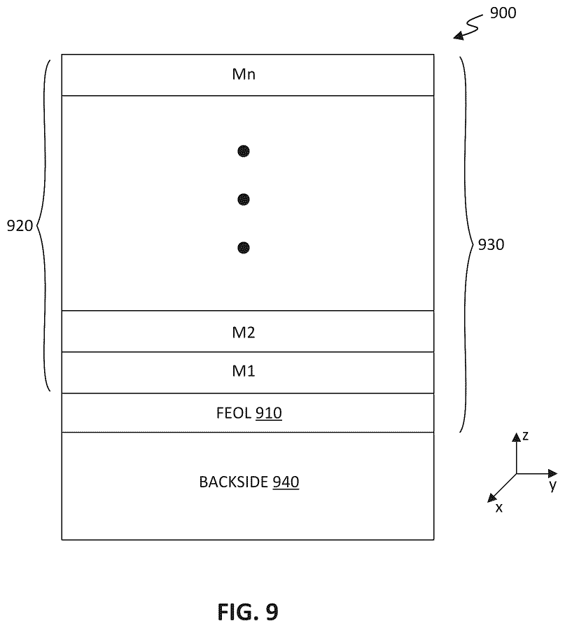

FIG. 9 provides a schematic illustration of a cross-sectional view of an example integrated circuit device (e.g., a chip) 900, according to some embodiments of the present disclosure. The IC device 900 may include transistors as well as other circuit elements (e.g., resistors, diodes) with channel material comprising an HP TFT material.

As shown in FIG. 9, the IC device 900 may include a front side 930 comprising an FEOL 910 that includes various logic layers, circuits, and devices to drive and control a logic IC. These circuits and devices may be configured for any number of functions, such as logic or compute transistors, input/output (I/O) transistors, access or switching transistors, and/or radio frequency (RF) transistors, to name a few examples. According to some embodiments, in addition to these devices and circuits, FEOL 910 may include, for example, one or more other layers or structures associated with the semiconductor devices and circuits. For example, the FEOL can also include a substrate and one or more dielectric layers that surround active and/or conductive portions of the devices and circuits. The FEOL may also include one or more conductive contacts that provide electrical contact to transistor elements such as gate structures, drain regions, or source regions. The FEOL may also include local interconnect (e.g., vias or lines) that connect contacts to interconnect features within the BEOL 920.

The front side 930 of the IC device 900 also includes a BEOL 920 including various metal interconnect layers (e.g., metal 1 through metal n, where n is any suitable integer). Various metal layers of the BEOL 920 may be used to interconnect the various inputs and outputs of the FEOL 910.

Generally speaking, each of the metal layers of the BEOL 920, e.g., each of the layers M1-Mn shown in FIG. 9, may include a via portion and a trench/interconnect portion. Typically, the trench portion of a metal layer is above the via portion, but, in other embodiments, a trench portion may be provided below a via portion of any given metal layer of the BEOL 920. The trench portion of a metal layer may be configured for transferring signals and power along metal lines (also sometimes referred to as “trenches”) extending in the x-y plane (e.g., in the x or y directions), while the via portion of a metal layer may be configured for transferring signals and power through metal vias extending in the z-direction, e.g., to any of the adjacent metal layers above or below. Accordingly, vias connect metal structures (e.g., metal lines or vias) from one metal layer to metal structures of an adjacent metal layer. While referred to as “metal” layers, various layers of the BEOL 920, e.g., layers M1-Mn shown in FIG. 9, may include certain patterns of conductive metals, e.g., copper (Cu) or aluminum (Al), or metal alloys, or more generally, patterns of an electrically conductive material, formed in an insulating medium such as an interlayer dielectric (ILD). The insulating medium may include any suitable ILD materials such as silicon oxide, silicon nitride, aluminum oxide, and/or silicon oxynitride. In various embodiments, any one or more of these layers may additionally include active devices (e.g., transistors, diodes) and/or passive devices (e.g., capacitors, resistors, inductors).

The IC device 900 may also include a backside 940. For example, the backside 940 may formed on the opposite side of a wafer from the front side 930. In various embodiments, the backside 940 may include any suitable elements to assist operation of the IC device 900. For example, the backside 940 may include various metal layers to deliver power to logic of the FEOL 910. In some embodiments, transistors or other circuit elements (e.g., diodes 108, 200, 400, 500 and resistors 106, 700) including HP TFT material may be formed on the backside 940 of the IC device 900.

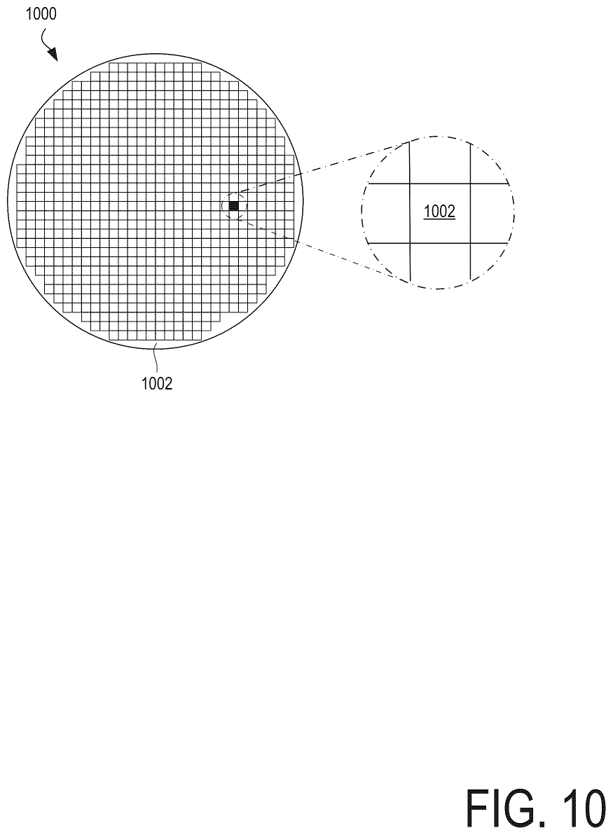

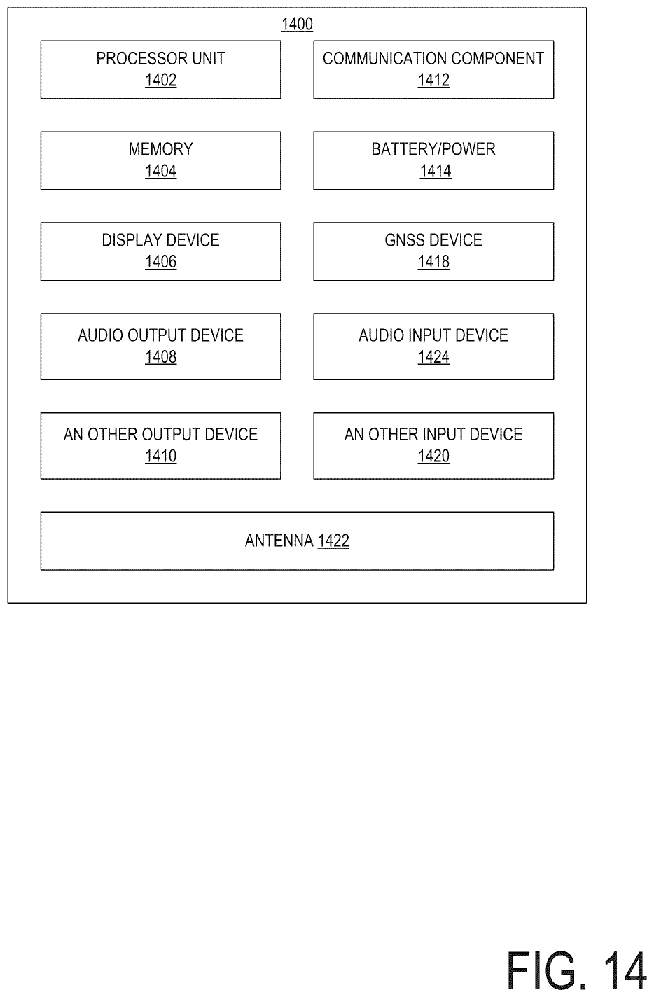

FIG. 10 is a top view of a wafer 1000 and dies 1002 wherein individual dies may include circuit elements comprising HP TFT material as described herein. The wafer 1000 may be composed of semiconductor material and may include one or more dies 1002 having integrated circuit structures formed on a surface of the wafer 1000. The individual dies 1002 may be a repeating unit of an integrated circuit product that includes any suitable integrated circuit. After the fabrication of the semiconductor product is complete, the wafer 1000 may undergo a singulation process in which the dies 1002 are separated from one another to provide discrete “chips” of the integrated circuit product. The die 1002 may include one or more transistors, supporting circuitry to route electrical signals to the transistors, passive components (e.g., signal traces, resistors, capacitors, or inductors), and/or any other integrated circuit components. In some embodiments, the wafer 1000 or the die 1002 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, OTP RAM, etc.), a logic device (e.g., an AND, OR, NAND, or NOR gate), or any other suitable circuit element. Multiple ones of these devices may be combined on a single die 1002. For example, a memory array formed by multiple memory devices may be formed on a same die 1002 as a processor unit (e.g., the processor unit 1402 of FIG. 14) or other logic that is configured to store information in the memory devices or execute instructions stored in the memory array.

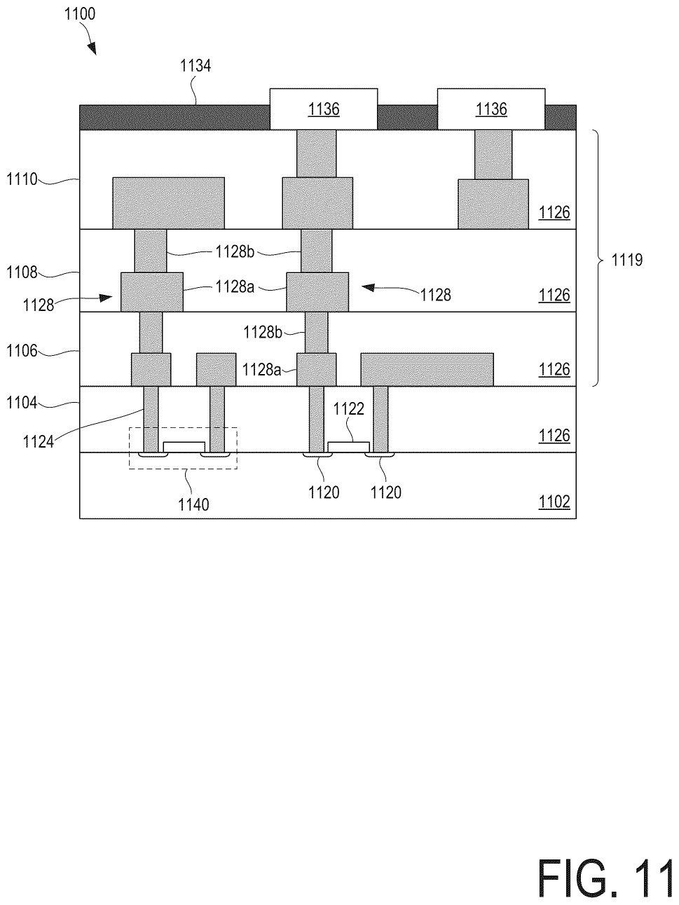

FIG. 11 is a cross-sectional side view of an integrated circuit device 1100 that may include circuit elements comprising HP TFT material as described herein. One or more of the integrated circuit devices 1100 may be included in one or more dies 1002 (FIG. 10). The integrated circuit device 1100 may be formed on a die substrate 1102 (e.g., the wafer 1000 of FIG. 10) and may be included in a die (e.g., the die 1002 of FIG. 10). The die substrate 1102 may be a semiconductor substrate composed of semiconductor material systems including, for example, n-type or p-type materials systems (or a combination of both). The die substrate 1102 may include, for example, a crystalline substrate formed using a bulk silicon or a silicon-on-insulator (SOI) substructure. In some embodiments, the die substrate 1102 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1102. Although a few examples of materials from which the die substrate 1102 may be formed are described here, any material that may serve as a foundation for an integrated circuit device 1100 may be used. The die substrate 1102 may be part of a singulated die (e.g., the dies 1002 of FIG. 10) or a wafer (e.g., the wafer 1000 of FIG. 10).

The integrated circuit device 1100 may include one or more device layers 1104 disposed on the die substrate 1102. The device layer 1104 may include features of one or more transistors 1140 (e.g., metal oxide semiconductor field-effect transistors (MOSFETs)) formed on the die substrate 1102. The transistors 1140 may include, for example, one or more source and/or drain (S/D) regions 1120, a gate 1122 to control current flow between the S/D regions 1120, and one or more S/D contacts 1124 to route electrical signals to/from the S/D regions 1120. The transistors 1140 may include additional features not depicted for the sake of clarity, such as device isolation regions, gate contacts, and the like. The transistors 1140 are not limited to the type and configuration depicted in FIG. 11 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

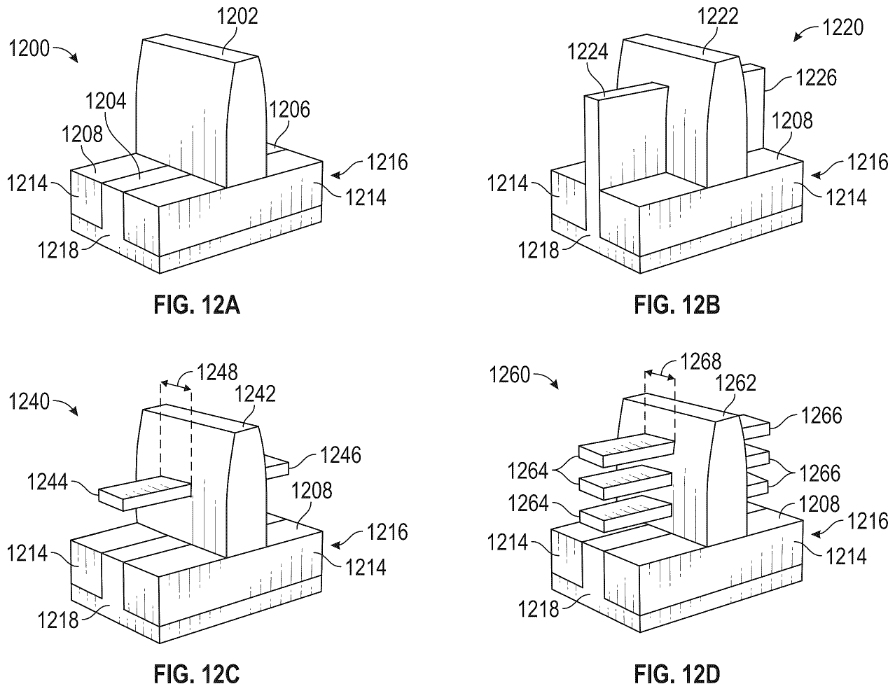

FIGS. 12A-12D are simplified perspective views of example planar, FinFET, gate-all-around, and stacked gate-all-around transistors. The transistors illustrated in FIGS. 12A-12D are formed on a substrate 1216 having a surface 1208. Isolation regions 1214 separate the source and drain regions of the transistors from other transistors and from a bulk region 1218 of the substrate 1216.

FIG. 12A is a perspective view of an example planar transistor 1200 comprising a gate 1202 that controls current flow between a source region 1204 and a drain region 1206. The transistor 1200 is planar in that the source region 1204 and the drain region 1206 are planar with respect to the substrate surface 1208.

FIG. 12B is a perspective view of an example FinFET transistor 1220 comprising a gate 1222 that controls current flow between a source region 1224 and a drain region 1226. The transistor 1220 is non-planar in that the source region 1224 and the drain region 1226 comprise “fins” that extend upwards from the substrate surface 1228. As the gate 1222 encompasses three sides of the semiconductor fin that extends from the source region 1224 to the drain region 1226, the transistor 1220 can be considered a tri-gate transistor. FIG. 12B illustrates one S/D fin extending through the gate 1222, but multiple S/D fins can extend through the gate of a FinFET transistor.

FIG. 12C is a perspective view of a gate-all-around (GAA) transistor 1240 comprising a gate 1242 that controls current flow between a source region 1244 and a drain region 1246. The transistor 1240 is non-planar in that the source region 1244 and the drain region 1246 are elevated from the substrate surface 1228.

FIG. 12D is a perspective view of a GAA transistor 1260 comprising a gate 1262 that controls current flow between multiple elevated source regions 1264 and multiple elevated drain regions 1266. The transistor 1260 is a stacked GAA transistor as the gate controls the flow of current between multiple elevated S/D regions stacked on top of each other. The transistors 1240 and 1260 are considered gate-all-around transistors as the gates encompass all sides of the semiconductor portions that extends from the source regions to the drain regions. The transistors 1240 and 1260 can alternatively be referred to as nanowire, nanosheet, or nanoribbon transistors depending on the width (e.g., widths 1248 and 1268 of transistors 1240 and 1260, respectively) of the semiconductor portions extending through the gate.

Returning to FIG. 11, a transistor 1140 may include a gate 1122 formed of at least two layers, a gate dielectric and a gate electrode. Examples and characteristics of gate dielectrics and gate electrodes have been described above.

In some embodiments, when viewed as a cross-section of the transistor 1140 along the source-channel-drain direction, the gate electrode may consist of a U-shaped structure that includes a bottom portion substantially parallel to the surface of the die substrate 1102 and two sidewall portions that are substantially perpendicular to the top surface of the die substrate 1102. In other embodiments, at least one of the metal layers that form the gate electrode may simply be a planar layer that is substantially parallel to the top surface of the die substrate 1102 and does not include sidewall portions substantially perpendicular to the top surface of the die substrate 1102. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1120 may be formed within the die substrate 1102 adjacent to the gate 1122 of individual transistors 1140. The S/D regions 1120 may be formed using an implantation/diffusion process or an etching/deposition process, for example. In the former process, dopants such as boron, aluminum, antimony, phosphorous, or arsenic may be ion-implanted into the die substrate 1102 to form the S/D regions 1120. An annealing process that activates the dopants and causes them to diffuse farther into the die substrate 1102 may follow the ion-implantation process. In the latter process, the die substrate 1102 may first be etched to form recesses at the locations of the S/D regions 1120. An epitaxial deposition process may then be carried out to fill the recesses with material that is used to fabricate the S/D regions 1120. In some implementations, the S/D regions 1120 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1120 may be formed using one or more alternate semiconductor materials such as germanium or a group III-V material or alloy. In further embodiments, one or more layers of metal and/or metal alloys may be used to form the S/D regions 1120. Further examples of materials that may be used to form the S/D regions are provided above.

Electrical signals, such as power and/or input/output (I/O) signals, may be routed to and/or from the devices (e.g., transistors 1140) of the device layer 1104 through one or more interconnect layers disposed on the device layer 1104 (illustrated in FIG. 11 as interconnect layers 1106-1110). For example, electrically conductive features of the device layer 1104 (e.g., the gate 1122 and the S/D contacts 1124) may be electrically coupled with the interconnect structures 1128 of the interconnect layers 1106-1110. The one or more interconnect layers 1106-1110 may form a metallization stack (also referred to as an “ILD stack”) 1119 of the integrated circuit device 1100.

The interconnect structures 1128 may be arranged within the interconnect layers 1106-1110 to route electrical signals according to a wide variety of designs; in particular, the arrangement is not limited to the particular configuration of interconnect structures 1128 depicted in FIG. 11. Although a particular number of interconnect layers 1106-1110 is depicted in FIG. 11, embodiments of the present disclosure include integrated circuit devices having more or fewer interconnect layers than depicted.

In some embodiments, the interconnect structures 1128 may include lines 1128a and/or vias 1128b filled with an electrically conductive material such as a metal. The lines 1128a may be arranged to route electrical signals in a direction of a plane that is substantially parallel with a surface of the die substrate 1102 upon which the device layer 1104 is formed. For example, the lines 1128a may route electrical signals in a direction in and out of the page. The vias 1128b may be arranged to route electrical signals in a direction of a plane that is substantially perpendicular to the surface of the die substrate 1102 upon which the device layer 1104 is formed. In some embodiments, the vias 1128b may electrically couple lines 1128a of different interconnect layers 1106-1110 together.

The interconnect layers 1106-1110 may include a dielectric material 1126 disposed between the interconnect structures 1128, as shown in FIG. 11. In some embodiments, dielectric material 1126 disposed between the interconnect structures 1128 in different ones of the interconnect layers 1106-1110 may have different compositions; in other embodiments, the composition of the dielectric material 1126 between different interconnect layers 1106-1110 may be the same. The device layer 1104 may include a dielectric material 1126 disposed between the transistors 1140 and a bottom layer of the metallization stack as well. The dielectric material 1126 included in the device layer 1104 may have a different composition than the dielectric material 1126 included in the interconnect layers 1106-1110; in other embodiments, the composition of the dielectric material 1126 in the device layer 1104 may be the same as a dielectric material 1126 included in any one of the interconnect layers 1106-1110.

A first interconnect layer 1106 (referred to as Metal 1 or “M1”) may be formed directly on the device layer 1104. In some embodiments, the first interconnect layer 1106 may include lines 1128a and/or vias 1128b, as shown. The lines 1128a of the first interconnect layer 1106 may be coupled with contacts (e.g., the S/D contacts 1124) of the device layer 1104. The vias 1128b of the first interconnect layer 1106 may be coupled with the lines 1128a of a second interconnect layer 1108.

The second interconnect layer 1108 (referred to as Metal 2 or “M2”) may be formed directly on the first interconnect layer 1106. In some embodiments, the second interconnect layer 1108 may include via 1128b to couple the lines 1128 of the second interconnect layer 1108 with the lines 1128a of a third interconnect layer 1110. Although the lines 1128a and the vias 1128b are structurally delineated with a line within individual interconnect layers for the sake of clarity, the lines 1128a and the vias 1128b may be structurally and/or materially contiguous (e.g., simultaneously filled during a dual-damascene process) in some embodiments.

The third interconnect layer 1110 (referred to as Metal 3 or “M3”) (and additional interconnect layers, as desired) may be formed in succession on the second interconnect layer 1108 according to similar techniques and configurations described in connection with the second interconnect layer 1108 or the first interconnect layer 1106. In some embodiments, the interconnect layers that are “higher up” in the metallization stack 1119 in the integrated circuit device 1100 (e.g., farther away from the device layer 1104) may be thicker that the interconnect layers that are lower in the metallization stack 1119, with lines 1128a and vias 1128b in the higher interconnect layers being thicker than those in the lower interconnect layers.

The integrated circuit device 1100 may include a solder resist material 1134 (e.g., polyimide or similar material) and one or more conductive contacts 1136 formed on the interconnect layers 1106-1110. In FIG. 11, the conductive contacts 1136 are illustrated as taking the form of bond pads. The conductive contacts 1136 may be electrically coupled with the interconnect structures 1128 and configured to route the electrical signals of the transistor(s) 1140 to external devices. For example, solder bonds may be formed on the one or more conductive contacts 1136 to mechanically and/or electrically couple an integrated circuit die including the integrated circuit device 1100 with another component (e.g., a printed circuit board). The integrated circuit device 1100 may include additional or alternate structures to route the electrical signals from the interconnect layers 1106-1110; for example, the conductive contacts 1136 may include other analogous features (e.g., posts) that route the electrical signals to external components.

In some embodiments in which the integrated circuit device 1100 is a double-sided die, the integrated circuit device 1100 may include another metallization stack (not shown) on the opposite side of the device layer(s) 1104. This metallization stack may include multiple interconnect layers as discussed above with reference to the interconnect layers 1106-1110, to provide conductive pathways (e.g., including conductive lines and vias) between the device layer(s) 1104 and additional conductive contacts (not shown) on the opposite side of the integrated circuit device 1100 from the conductive contacts 1136.

In other embodiments in which the integrated circuit device 1100 is a double-sided die, the integrated circuit device 1100 may include one or more through silicon vias (TSVs) through the die substrate 1102; these TSVs may make contact with the device layer(s) 1104, and may provide conductive pathways between the device layer(s) 1104 and additional conductive contacts (not shown) on the opposite side of the integrated circuit device 1100 from the conductive contacts 1136. In some embodiments, TSVs extending through the substrate can be used for routing power and ground signals from conductive contacts on the opposite side of the integrated circuit device 1100 from the conductive contacts 1136 to the transistors 1140 and any other components integrated into the integrated circuit device (e.g., die) 1100, and the metallization stack 1119 can be used to route I/O signals from the conductive contacts 1136 to transistors 1140 and any other components integrated into the integrated circuit device (e.g., die) 1100.

Multiple integrated circuit devices 1100 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

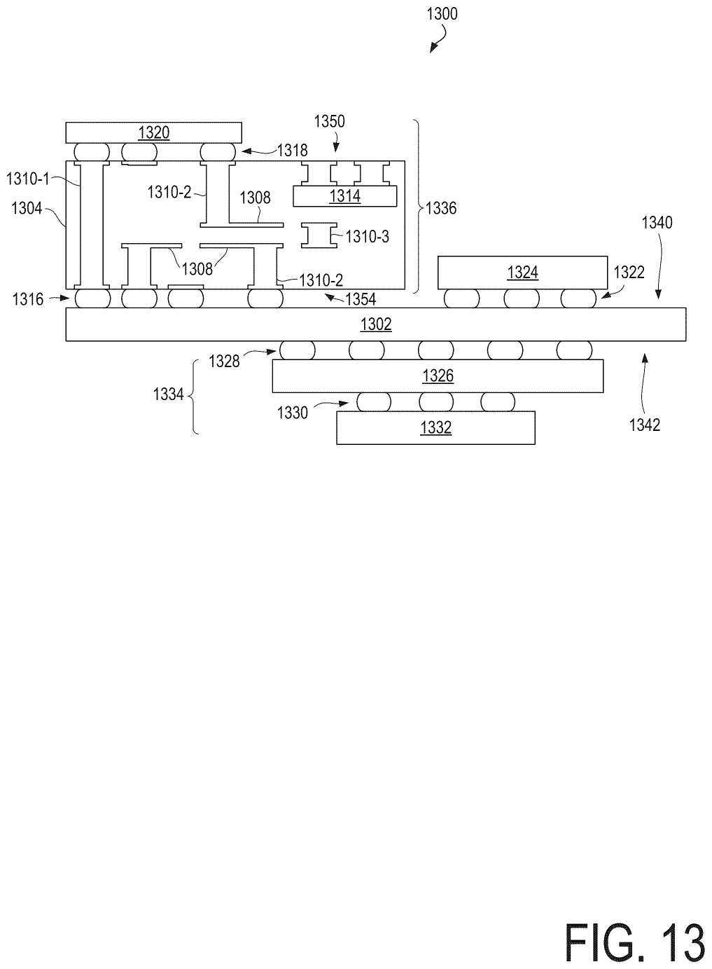

FIG. 13 is a cross-sectional side view of an integrated circuit device assembly 1300. The integrated circuit device assembly 1300 includes a number of components disposed on a circuit board 1302 (which may be a motherboard, system board, mainboard, etc.). The integrated circuit device assembly 1300 includes components disposed on a first face 1340 of the circuit board 1302 and an opposing second face 1342 of the circuit board 1302; generally, components may be disposed on one or both faces 1340 and 1342.

In some embodiments, the circuit board 1302 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1302. In other embodiments, the circuit board 1302 may be a non-PCB substrate. The integrated circuit device assembly 1300 illustrated in FIG. 13 includes a package-on-interposer structure 1336 coupled to the first face 1340 of the circuit board 1302 by coupling components 1316. The coupling components 1316 may electrically and mechanically couple the package-on-interposer structure 1336 to the circuit board 1302, and may include solder balls (as shown in FIG. 13), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1336 may include an integrated circuit component 1320 coupled to an interposer 1304 by coupling components 1318. The coupling components 1318 may take any suitable form for the application, such as the forms discussed above with reference to the coupling components 1316. Although a single integrated circuit component 1320 is shown in FIG. 13, multiple integrated circuit components may be coupled to the interposer 1304; indeed, additional interposers may be coupled to the interposer 1304. The interposer 1304 may provide an intervening substrate used to bridge the circuit board 1302 and the integrated circuit component 1320.

The integrated circuit component 1320 may be a packaged or unpacked integrated circuit product that includes one or more integrated circuit dies (e.g., the die 1002 of FIG. 10, the integrated circuit device 1100 of FIG. 11, etc.) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1320, a single monolithic integrated circuit die comprises solder bumps attached to contacts on the die. The solder bumps allow the die to be directly attached to the interposer 1304. The integrated circuit component 1320 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1320 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1320 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1320 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1304 may spread connections to a wider pitch or reroute a connection to a different connection. For example, the interposer 1304 may couple the integrated circuit component 1320 to a set of ball grid array (BGA) conductive contacts of the coupling components 1316 for coupling to the circuit board 1302. In the embodiment illustrated in FIG. 13, the integrated circuit component 1320 and the circuit board 1302 are attached to opposing sides of the interposer 1304; in other embodiments, the integrated circuit component 1320 and the circuit board 1302 may be attached to a same side of the interposer 1304. In some embodiments, three or more components may be interconnected by way of the interposer 1304.

In some embodiments, the interposer 1304 may be formed as a PCB, including multiple metal layers separated from one another by layers of dielectric material and interconnected by electrically conductive vias. In some embodiments, the interposer 1304 may be formed of an epoxy resin, a fiberglass-reinforced epoxy resin, an epoxy resin with inorganic fillers, a ceramic material, or a polymer material such as polyimide. In some embodiments, the interposer 1304 may be formed of alternate rigid or flexible materials that may include the same materials described above for use in a semiconductor substrate, such as silicon, germanium, and other group III-V and group IV materials. The interposer 1304 may include metal interconnects 1308 and vias 1310, including but not limited to through hole vias 1310-1 (that extend from a first face 1350 of the interposer 1304 to a second face 1354 of the interposer 1304), blind vias 1310-2 (that extend from the first or second faces 1350 or 1354 of the interposer 1304 to an internal metal layer), and buried vias 1310-3 (that connect internal metal layers).

In some embodiments, the interposer 1304 can comprise a silicon interposer. Through silicon vias (TSV) extending through the silicon interposer can connect connections on a first face of a silicon interposer to an opposing second face of the silicon interposer. In some embodiments, an interposer 1304 comprising a silicon interposer can further comprise one or more routing layers to route connections on a first face of the interposer 1304 to an opposing second face of the interposer 1304.

The interposer 1304 may further include embedded devices 1314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1304. The package-on-interposer structure 1336 may take the form of any of the package-on-interposer structures known in the art.

The integrated circuit device assembly 1300 may include an integrated circuit component 1324 coupled to the first face 1340 of the circuit board 1302 by coupling components 1322. The coupling components 1322 may take the form of any of the embodiments discussed above with reference to the coupling components 1316, and the integrated circuit component 1324 may take the form of any of the embodiments discussed above with reference to the integrated circuit component 1320.

The integrated circuit device assembly 1300 illustrated in FIG. 13 includes a package-on-package structure 1334 coupled to the second face 1342 of the circuit board 1302 by coupling components 1328. The package-on-package structure 1334 may include an integrated circuit component 1326 and an integrated circuit component 1332 coupled together by coupling components 1330 such that the integrated circuit component 1326 is disposed between the circuit board 1302 and the integrated circuit component 1332. The coupling components 1328 and 1330 may take the form of any of the embodiments of the coupling components 1316 discussed above, and the integrated circuit components 1326 and 1332 may take the form of any of the embodiments of the integrated circuit component 1320 discussed above. The package-on-package structure 1334 may be configured in accordance with any of the package-on-package structures known in the art.

FIG. 14 is a block diagram of an example electrical device 1400 that may include varactors as disclosed herein. For example, any suitable ones of the components of the electrical device 1400 may include one or more of the integrated circuit device assemblies 1300, integrated circuit components 1320, integrated circuit devices 1100, or integrated circuit dies 1002 disclosed herein. A number of components are illustrated in FIG. 14 as included in the electrical device 1400, but any one or more of these components may be omitted or duplicated, as suitable for the application. In some embodiments, some or all of the components included in the electrical device 1400 may be attached to one or more motherboards mainboards, or system boards. In some embodiments, one or more of these components are fabricated onto a single system-on-a-chip (SoC) die.

Additionally, in various embodiments, the electrical device 1400 may not include one or more of the components illustrated in FIG. 14, but the electrical device 1400 may include interface circuitry for coupling to the one or more components. For example, the electrical device 1400 may not include a display device 1406, but may include display device interface circuitry (e.g., a connector and driver circuitry) to which a display device 1406 may be coupled. In another set of examples, the electrical device 1400 may not include an audio input device 1424 or an audio output device 1408, but may include audio input or output device interface circuitry (e.g., connectors and supporting circuitry) to which an audio input device 1424 or audio output device 1408 may be coupled.

The electrical device 1400 may include one or more processor units 1402 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1402 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1400 may include a memory 1404, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1404 may include memory that is located on the same integrated circuit die as the processor unit 1402. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1400 can comprise one or more processor units 1402 that are heterogeneous or asymmetric to another processor unit 1402 in the electrical device 1400. There can be a variety of differences between the processing units 1402 in a system in terms of a spectrum of metrics of merit including architectural, microarchitectural, thermal, power consumption characteristics, and the like. These differences can effectively manifest themselves as asymmetry and heterogeneity among the processor units 1402 in the electrical device 1400.

In some embodiments, the electrical device 1400 may include a communication component 1412 (e.g., one or more communication components). For example, the communication component 1412 can manage wireless communications for the transfer of data to and from the electrical device 1400. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1412 may operate in accordance with other wireless protocols in other embodiments. The electrical device 1400 may include an antenna 1422 to facilitate wireless communications and/or to receive other wireless communications (such as AM or FM radio transmissions).

In some embodiments, the communication component 1412 may manage wired communications, such as electrical, optical, or any other suitable communication protocols (e.g., IEEE 802.3 Ethernet standards). As noted above, the communication component 1412 may include multiple communication components. For instance, a first communication component 1412 may be dedicated to shorter-range wireless communications such as Wi-Fi or Bluetooth, and a second communication component 1412 may be dedicated to longer-range wireless communications such as global positioning system (GPS), EDGE, GPRS, CDMA, WiMAX, LTE, EV-DO, or others. In some embodiments, a first communication component 1412 may be dedicated to wireless communications, and a second communication component 1412 may be dedicated to wired communications.

The electrical device 1400 may include battery/power circuitry 1414. The battery/power circuitry 1414 may include one or more energy storage devices (e.g., batteries or capacitors) and/or circuitry for coupling components of the electrical device 1400 to an energy source separate from the electrical device 1400 (e.g., AC line power).

The electrical device 1400 may include a display device 1406 (or corresponding interface circuitry, as discussed above). The display device 1406 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1400 may include an audio output device 1408 (or corresponding interface circuitry, as discussed above). The audio output device 1408 may include any embedded or wired or wirelessly connected external device that generates an audible indicator, such speakers, headsets, or earbuds.

The electrical device 1400 may include an audio input device 1424 (or corresponding interface circuitry, as discussed above). The audio input device 1424 may include any embedded or wired or wirelessly connected device that generates a signal representative of a sound, such as microphones, microphone arrays, or digital instruments (e.g., instruments having a musical instrument digital interface (MIDI) output). The electrical device 1400 may include a Global Navigation Satellite System (GNSS) device 1418 (or corresponding interface circuitry, as discussed above), such as a Global Positioning System (GPS) device. The GNSS device 1418 may be in communication with a satellite-based system and may determine a geolocation of the electrical device 1400 based on information received from one or more GNSS satellites, as known in the art.

The electrical device 1400 may include another output device 1410 (or corresponding interface circuitry, as discussed above). Examples of the other output device 1410 may include an audio codec, a video codec, a printer, a wired or wireless transmitter for providing information to other devices, or an additional storage device.

The electrical device 1400 may include another input device 1420 (or corresponding interface circuitry, as discussed above). Examples of the other input device 1420 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1400 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1400 may be any other electronic device that processes data. In some embodiments, the electrical device 1400 may comprise multiple discrete physical components. Given the range of devices that the electrical device 1400 can be manifested as in various embodiments, in some embodiments, the electrical device 1400 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of embodiments has been described with reference to specific example embodiments, various modifications and changes may be made to these embodiments without departing from the broader scope of embodiments of the present disclosure.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first gate and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” “according to some embodiments,” “in accordance with embodiments,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 10⁷ Siemens per meter (S/m) at 20 degrees Celsius. Examples of such materials include Cu, Ag, Al, Au, W, Zn and Ni.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices. The term “signal” may refer to at least one current signal, voltage signal, magnetic signal, or data/clock signal.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

Unless otherwise specified in the specific context of use, the term “predominantly” means more than 50%, or more than half. For example, a composition that is predominantly a first constituent means more than half of the composition (e.g., by volume) is the first constituent (e.g., >50 at. %). The term “primarily” means the most, or greatest, part. For example, a composition that is primarily a first constituent means the composition has more of the first constituent (e.g., by volume) than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

As used throughout this description, and in the claims, a list of items joined by the term “at least one of” or “one or more of” can mean any combination of the listed terms.

Unless otherwise specified in the explicit context of their use, the terms “substantially equal,” “about equal” or “approximately equal” mean that there is no more than incidental variation between two things so described. In the art, such variation is typically no more than +/−10% of a predetermined target value.

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

Although the figures may illustrate embodiments where structures are substantially aligned to Cartesian axes (e.g., device structures having substantially vertical sidewalls), positive and negative (re-entrant) sloped feature sidewalls often occur in practice. For example, manufacturing non-idealities may cause one or more structural features to have sloped sidewalls. Thus, attributes illustrated are idealized merely for the sake of clearly describing salient features. It is to be understood that schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Example 1 includes an integrated circuit device comprising a resistor formed on a non-crystalline substrate, the resistor comprising a gate electrode; a gate dielectric in contact with the gate electrode; a source electrode and a drain electrode; and a thin film transistor TFT channel material coupled between the source electrode and the drain electrode.

Example 2 includes the subject matter of Example 1, and wherein the TFT channel material has a charge carrier mobility within a range of 5 cm2/(V·s) to 700 cm2/(V·s) and a bandgap voltage within a range of 1.15 eV to 6.5 eV at 300 degrees Kelvin.

Example 3 includes the subject matter of any of Examples 1 and 2, and wherein the integrated circuit device comprises an integrated circuit die with a front side comprising a plurality of transistors and interconnect layers and a back side comprising the resistor.

Example 4 includes the subject matter of any of Examples 1-3, and wherein the non-crystalline substrate comprises silicon oxide, silicon nitride, a metal oxide, or silicon oxynitride.

Example 5 includes the subject matter of any of Examples 1-4, and further including a diode comprising a first conductive contact, a second conductive contact, and the TFT channel material coupled between the first conductive contact and the second conductive contact.

Example 6 includes the subject matter of any of Examples 1-5, and further including a circuit implementing electrostatic discharge protection, wherein the circuit comprises the resistor and the diode.

Example 7 includes the subject matter of any of Examples 1-6, and wherein the first conductive contact is substantially parallel to the second conductive contact, and wherein the TFT channel material is substantially orthogonal to the first conductive contact and the second conductive contact.

Example 8 includes the subject matter of any of Examples 1-7, and wherein the TFT channel material is substantially parallel to the first conductive contact and second conductive contact in a horizontal grating configuration.

Example 9 includes the subject matter of any of Examples 1-8, and wherein the TFT channel material is between the first conductive contact and second conductive contact in a vertical stack.

Example 10 includes the subject matter of any of Examples 1-9, and wherein the back side of the integrated circuit die further comprises the diode.

Example 11 includes the subject matter of any of Examples 1-10, and further including an integrated circuit die comprising the resistor.

Example 12 includes the subject matter of any of Examples 1-11, and further including a circuit board coupled to the integrated circuit die.

Example 13 includes the subject matter of any of Examples 1-12, and further including at least one of a network interface, battery, or memory coupled to the integrated circuit die.

Example 14 includes the subject matter of any of Examples 1-13, and wherein the TFT channel material and the first conductive contact form a Schottky barrier.

Example 15 includes the subject matter of any of Examples 1-14, and wherein the TFT channel material and the second conductive contact form an ohmic contact.

Example 16 includes an apparatus comprising a diode formed on a non-crystalline substrate, the diode comprising a first conductive contact; a second conductive contact; and a thin film transistor (TFT) channel material coupled between the first conductive contact and the second conductive contact.

Example 17 includes the subject matter of Example 16, and wherein the TFT channel material and the first conductive contact form a Schottky barrier.

Example 18 includes the subject matter of any of Examples 16 and 17, and wherein the TFT channel material and the second conductive contact form an ohmic contact.

Example 19 includes the subject matter of any of Examples 16-18, and wherein the TFT channel material has a charge carrier mobility within a range of 5 cm2/(V·s) to 700 cm2/(V·s) and a bandgap voltage within a range of 1.15 eV to 6.5 eV at 300 degrees Kelvin.

Example 20 includes the subject matter of any of Examples 16-19, and wherein the first conductive contact is substantially parallel to the second conductive contact, and wherein the TFT channel material is substantially orthogonal to the first conductive contact and the second conductive contact.

Example 21 includes the subject matter of any of Examples 16-20, and wherein the TFT channel material is substantially parallel to the first conductive contact and second conductive contact in a horizontal grating configuration.

Example 22 includes the subject matter of any of Examples 16-21, and wherein the TFT channel material is between the first conductive contact and second conductive contact in a vertical stack.

Example 23 includes the subject matter of any of Examples 16-22, and wherein the integrated circuit device comprises an integrated circuit die with a front side comprising a plurality of transistors and interconnect layers and a back side comprising the diode.

Example 24 includes the subject matter of any of Examples 16-23, and wherein the non-crystalline substrate comprises silicon oxide, silicon nitride, a metal oxide, or silicon oxynitride.

Example 25 includes the subject matter of any of Examples 16-24, and further including a resistor formed on the non-crystalline substrate, the resistor comprising a gate electrode; a gate dielectric in contact with the gate electrode; a source electrode and a drain electrode; and the TFT channel material, wherein the TFT channel material is coupled between the source electrode and the drain electrode.

Example 26 includes the subject matter of any of Examples 16-25, and further including an integrated circuit die comprising the diode.

Example 27 includes the subject matter of any of Examples 16-26, and further including a circuit board coupled to the integrated circuit die.

Example 28 includes the subject matter of any of Examples 16-27, and further including at least one of a network interface, battery, or memory coupled to the integrated circuit die.

Example 29 includes the subject matter of any of Examples 16-28, and wherein the back side of the integrated circuit die comprises the diode and the resistor.

Example 30 includes the subject matter of any of Examples 16-29, and further including a circuit implementing electrostatic discharge protection, wherein the circuit comprises the resistor and the diode.

Example 31 includes the subject matter of any of Examples 16-30, and further including a resistor comprising a gate electrode; a gate dielectric in contact with the gate electrode; a source electrode and a drain electrode; and the TFT channel material coupled between the source electrode and the drain electrode.

Example 32 includes a method comprising forming a resistor on a non-crystalline substrate by forming a thin film transistor (TFT) channel material on the substrate; forming a gate dielectric on the TFT channel material; forming a gate electrode on the gate dielectric; and forming source and drain electrodes on the TFT channel material.

Example 33 includes the subject matter of Example 32, and further including forming a diode on the non-crystalline substrate by forming a first conductive contact and a second conductive contact, wherein the TFT channel material is coupled between the first conductive contact and the second conductive contact.

Example 34 includes the subject matter of any of Examples 32 and 33, and wherein the TFT channel material has a charge carrier mobility within a range of 5 cm2/(V·s) to 700 cm2/(V·s) and a bandgap voltage within a range of 1.15 eV to 6.5 eV at 300 degrees Kelvin.

Example 35 includes the subject matter of any of Examples 32-34, and further including forming an integrated circuit die with a front side comprising a plurality of transistors and interconnect layers and a back side comprising the resistor.

Example 36 includes the subject matter of any of Examples 32-35, and wherein the non-crystalline substrate comprises silicon oxide, silicon nitride, a metal oxide, or silicon oxynitride.

Example 37 includes the subject matter of any of Examples 32-36, and further including forming a circuit implementing electrostatic discharge protection, wherein the circuit comprises the resistor and the diode.

Example 38 includes the subject matter of any of Examples 32-37, and wherein the first conductive contact is substantially parallel to the second conductive contact, and wherein the TFT channel material is substantially orthogonal to the first conductive contact and the second conductive contact.

Example 39 includes the subject matter of any of Examples 32-38, and wherein the TFT channel material is substantially parallel to the first conductive contact and second conductive contact in a horizontal grating configuration.

Example 40 includes the subject matter of any of Examples 32-39, and wherein the TFT channel material is between the first conductive contact and second conductive contact in a vertical stack.

Example 41 includes the subject matter of any of Examples 32-40, and further including forming the diode on the back side of the integrated circuit die.

Example 42 includes the subject matter of any of Examples 32-41, and further including coupling a circuit board to the integrated circuit die.

Example 43 includes the subject matter of any of Examples 32-42, and further including coupling at least one of a network interface, battery, or memory to the integrated circuit die.

Example 44 includes the subject matter of any of Examples 32-43, and wherein the TFT channel material and the first conductive contact form a Schottky barrier.

Example 45 includes the subject matter of any of Examples 32-44, and wherein the TFT channel material and the second conductive contact form an ohmic contact.

1. An integrated circuit device comprising:
a resistor formed on a non-crystalline substrate, the resistor comprising:
a gate electrode;
a gate dielectric in contact with the gate electrode;
a source electrode and a drain electrode; and
a thin film transistor (TFT) channel material coupled between the source electrode and the drain electrode.

2. The integrated circuit device of claim 1, wherein the TFT channel material has a charge carrier mobility within a range of 5 cm²/(V·s) to 700 cm²/(V·s) and a bandgap voltage within a range of 1.15 eV to 6.5 eV at 300 degrees Kelvin.

3. The integrated circuit device of claim 1, wherein the integrated circuit device comprises an integrated circuit die with a front side comprising a plurality of transistors and interconnect layers and a back side comprising the resistor.

4. The integrated circuit device of claim 1, wherein the non-crystalline substrate comprises silicon oxide, silicon nitride, a metal oxide, or silicon oxynitride.

5. The integrated circuit device of claim 1, further comprising a diode comprising a first conductive contact, a second conductive contact, and the TFT channel material coupled between the first conductive contact and the second conductive contact.

6. The integrated circuit device of claim 5, further comprising a circuit implementing electrostatic discharge protection, wherein the circuit comprises the resistor and the diode.

7. The integrated circuit device of claim 5, wherein the first conductive contact is substantially parallel to the second conductive contact, and wherein the TFT channel material is substantially orthogonal to the first conductive contact and the second conductive contact.

8. The integrated circuit device of claim 5, wherein the TFT channel material is substantially parallel to the first conductive contact and second conductive contact in a horizontal grating configuration.

9. The integrated circuit device of claim 5, wherein the TFT channel material is between the first conductive contact and second conductive contact in a vertical stack.

10. The integrated circuit device of claim 5, wherein the integrated circuit device comprises an integrated circuit die with a front side comprising a plurality of transistors and interconnect layers and a back side comprising the resistor, wherein the back side of the integrated circuit die further comprises the diode.

11. The integrated circuit device of claim 1, further comprising an integrated circuit die comprising the resistor.

12. The integrated circuit device of claim 11, further comprising a circuit board coupled to the integrated circuit die.

13. The integrated circuit device of claim 11, further comprising at least one of a network interface, battery, or memory coupled to the integrated circuit die.

14. An apparatus comprising:
a diode formed on a non-crystalline substrate, the diode comprising:
a first conductive contact;
a second conductive contact; and
a thin film transistor (TFT) channel material coupled between the first conductive contact and the second conductive contact.

15. The apparatus of claim 14, wherein the TFT channel material and the first conductive contact form a Schottky barrier.

16. The apparatus of claim 15, wherein the TFT channel material and the second conductive contact form an ohmic contact.

17. The apparatus of claim 14, wherein the TFT channel material has a charge carrier mobility within a range of 50 cm²/(V·s) to 700 cm²/(V·s) and a bandgap voltage within a range of 1.15 eV to 6.5 eV at 300 degrees Kelvin.

18. The apparatus of claim 14, further comprising:
a resistor comprising:
a gate electrode;
a gate dielectric in contact with the gate electrode;
a source electrode and a drain electrode; and
the TFT channel material coupled between the source electrode and the drain electrode.

19. A method comprising:
forming a resistor on a non-crystalline substrate by:
forming a thin film transistor (TFT) channel material on the substrate;
forming a gate dielectric on the TFT channel material;
forming a gate electrode on the gate dielectric; and
forming source and drain electrodes on the TFT channel material.

20. The method of claim 19, further comprising forming a diode on the non-crystalline substrate by forming a first conductive contact and a second conductive contact, wherein the TFT channel material is coupled between the first conductive contact and the second conductive contact.
